(19) United States
(12) Patent Application Publication
(10) Pub. No.: US 2009/0053833 A1
(43) Pub. Date: Feb. 26, 2009

(54) Method of Manufacturing Magnetic Multi-layered Film

(75) Inventors: Yukio Kikuchi, Tsukuba-shi (JP); Tadashi Morita, Tsukuba-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, Inc., Kanagawa-ken (JP)

(21) Appl. No.: 11/813,335

(22) PCT Filed: Dec. 29, 2005
(86) PCT No.: PCT/JP2005/024152

§ 371 Date: Jul. 14, 2008

(30) Foreign Application Priority Data
Jan. 5, 2005 (JP) 2005-000403

(51) Int. Cl. H01L 21/00

(52) U.S. Cl. 438/3; 257/E21.001

(57) ABSTRACT

A method of manufacturing a magnetic multi-layered film including: a first magnetic layer forming step of forming a first magnetic layer on a substrate; a non-magnetic layer forming step of forming a non-magnetic layer on the first magnetic layer; and a second magnetic layer forming step of forming a second magnetic layer on the non-magnetic layer, the method further including, before the non-magnetic layer forming step, a plasma treatment step of introducing the substrate into a plasma treatment apparatus and treating the substrate with inductive coupling-type plasma, with the substrate being electrically insulated from the plasma treatment apparatus.

### TECHNICAL FIELD

The present invention relates to a method of manufacturing a magnetic multi-layered film that is adapted to formation of a film constituting a semiconductor device, such as a Giant Magneto-Resistance (GMR) spin valve constituting a magnetic head, a Tunneling Magneto-Resistance (TMR) device constituting a magnetic random access memory (MRAM) and so on.

Priority is claimed on Japanese Patent Application No. 2005-000403, filed Jan. 5, 2005, the contents of which are incorporated herein by reference.

### BACKGROUND ART

An MRAM which has been developed in recent years is constituted of a tunnel junction device formed by a TMR film.

FIG. 8A is a side sectional view of a tunnel junction device. The tunnel junction device 10 includes a first magnetic layer (pinned layer) 14, a non-magnetic layer (tunnel barrier layer) 15, a second magnetic layer (free layer) 16, and so on, which are laminated. The tunnel barrier layer 15 is made of an electrical insulating material. In addition, a magnetization direction in a plane of the pinned layer 14 keeps constant and a magnetization direction in a plane of the free layer 16 can be inverted by an external magnetic field. Resistance of the tunnel junction device 10 is varied depending on whether the magnetization direction of the pinned layer 14 is parallel or anti-parallel to the magnetization direction of the free layer 16; and accordingly, the intensity of current flowing through the tunnel barrier layer 15 is varied when a voltage is applied to the tunnel junction device 10 in its thickness direction (which is called a TMR effect). Thus, a binary value of ‘1’ or ‘0’ can be read by detecting the intensity of current.

[Patent Document 1] Japanese Unexamined Patent Application, First Publication No. 2003-86866

### DISCLOSURE OF THE INVENTION

### Problems to be Solved by the Invention

In such a tunnel junction device, if there is a deviation in film thickness in each layers of the pinned layer 14 and the below layers, the tunnel barrier layer 15 laminated on the pinned layer 14 becomes uneven, as shown FIG. 8B.

This may cause a magnetic Neel coupling between the pinned layer 14 and the free layer 16 with the tunnel barrier layer 14 interposed therebetween. As a result, preservation power of the magnetization direction in the free layer 16 increases, and accordingly, a high magnetic field is required to invert the magnetization direction and the magnitude of the required magnetic field becomes irregular. Accordingly, there is a need to flatten the tunnel barrier layer 15.

In addition, Patent Document 1 discloses a method of manufacturing a spin valve-type giant magnetic resistive thin film which is a kind of magnetic multi-layered film. The spin valve-type giant magneto-resistance thin film includes a buffer layer deposited on a substrate and a non-magnetic conductive layer with a magnetization pinned layer and a magnetic free layer interposed therebetween. In addition, a technique disclosed in Patent Document 1 is characterized in that at least one of a plurality of interfaces formed between the non-magnetic conductive layer and the buffer layer is subjected to a plasma treatment.

However, this plasma treatment is performed using a capacitive coupling-type apparatus having a parallel plate electrode structure. In this case, since a bias voltage is applied to the substrate, ions of a process gas such as argon are introduced into the substrate. As a result, a surface of the magnetic multi-layered film is damaged by being etched, for example, thereby deteriorating the performance of the magnetic multi-layered film.

To overcome the above problems, it is an object of the present invention to provide a method of manufacturing a magnetic multi-layered film, which is capable of flattening a non-magnetic layer without deteriorating the performance of the magnetic multi-layered film.

### Means for Solving the Problems

In order to achieve the above-mentioned object, according to an aspect of the present invention, there is provided a method of manufacturing a magnetic multi-layered film, including a first magnetic layer forming step of forming a first magnetic layer on a substrate, a non-magnetic layer forming step of forming a non-magnetic layer on the first magnetic layer, and a second magnetic layer forming step of forming a second magnetic layer on the non-magnetic layer, the method further including, before the non-magnetic layer forming step, a plasma treatment step of introducing the substrate into a plasma treatment apparatus and treating the substrate with inductive coupling-type plasma, with the substrate being electrically insulated from the plasma treatment apparatus.

According to another aspect of the present invention, there is provided a method of manufacturing a magnetic multi-layered film, including a first magnetic layer forming step of forming a first magnetic layer on a substrate, a non-magnetic layer forming step of forming a non-magnetic layer on the first magnetic layer, and a second magnetic layer forming step of forming a second magnetic layer on the non-magnetic layer, the method further including, before the non-magnetic layer forming step, a plasma treatment step of introducing the substrate into a plasma treatment apparatus and treating the substrate with inductive coupling-type plasma, with the substrate being grounded.

With the above configurations, ions generated by the plasma are not introduced into the substrate. Accordingly, the surface of the magnetic multi-layered film can be planarized before the non-magnetic layer forming step, without the magnetic multi-layered film being damaged by being etched, or the like. Accordingly, the non-magnetic layer can be flatly laminated without deteriorating the performance of the magnetic multi-layered film.

Preferably, power supplied to the plasma treatment apparatus in the plasma treatment step is not less than 5 W and not more than 400 W.

With this configuration, the surface of the magnetic multi-layered film can be prevented from being etched.

Accordingly, the performance of the magnetic multi-layered film is not deteriorated.

Preferably, plasma treatment time is within 180 seconds in the plasma treatment step.

With this configuration, the surface of the magnetic multi-layered film can be prevented from being etched.

Accordingly, the performance of the magnetic multi-layered film is not deteriorated.

Preferably, the plasma treatment is performed on a surface of the first magnetic layer contacting the non-magnetic layer in the plasma treatment step.

With this configuration, since the non-magnetic layer is laminated in contact with the first magnetic layer, the non-magnetic layer can be most effectively flattened by planarizing the surface of the first magnetic layer.

Preferably, the method further includes, before the first magnetic layer forming step, a first underlying layer forming step of forming a first underlying layer on the substrate, a second underlying layer forming step of forming a second underlying layer on the first underlying layer, and an anti-ferromagnetic layer forming step of forming an anti-ferromagnetic layer on the second underlying layer, and, before the second underlying layer forming step, the plasma treatment is performed on a surface of the first underlying layer in the plasma treatment step.

With this configuration, the non-magnetic layer can be flatly formed without deteriorating the performance of the magnetic multi-layered film.

Preferably, the magnetic multi-layered film is a tunneling magneto-resistance film and the non-magnetic layer is a tunnel barrier layer.

With this configuration, even when a small number of magnetic multi-layered films are obtained from one substrate, the non-magnetic layer can be flatly formed while minimizing a decrease in the production efficiency accompanied by the plasma treatment.

### Effects of the Invention

According to the present invention, with the above configuration, ions generated by plasma are not introduced into the substrate. Accordingly, the surface of the magnetic multi-layered film can be flattened before the non-magnetic layer is formed, without being damaged by being etched, for example, thereby stacking the non-magnetic layer flatly without deteriorating the performance of the magnetic multi-layered film.

### BRIEF DESCRIPTION OF THE DRAWINGS

FIG. 1 is a side sectional view showing a tunnel junction device.

FIG. 2 is a schematic view showing a configuration of an apparatus for manufacturing a magnetic multi-layered film according to an embodiment of the present invention.

FIG. 3 is a schematic view showing a configuration of a plasma treatment apparatus.

FIG. 4A is an explanatory view illustrating a method of manufacturing the magnetic multi-layered film according to the embodiment of the present invention.

FIG. 4B is an explanatory view illustrating a method of manufacturing the magnetic multi-layered film according to the embodiment of the present invention.

FIG. 4C is an explanatory view illustrating a method of manufacturing the magnetic multi-layered film according to the embodiment of the present invention.

FIG. 5 is a graph showing a relationship between power supplied to an RF antenna and an etching condition.

FIG. 6 is a graph showing a relationship between a plasma treatment time and a surface roughness of a pinned layer.

FIG. 7 is a graph showing a VSM analysis result of a magnetic multi-layered film.

FIG. 8A is an explanatory view of a Neel coupling.

FIG. 8B is an explanatory view of a Neel coupling.

### REFERENCE NUMERALS

5: Substrate
12a: First underlying layer
12b: Second underlying layer
13: Anti-ferromagnetic layer
14: Pinned layer (first magnetic layer)
15: Tunnel barrier layer (non-magnetic layer)
16: Free layer (second magnetic layer)
60: Plasma treatment apparatus

### BEST MODE FOR CARRYING OUT THE INVENTION

Hereinafter, embodiments of the present invention will be described with reference to the accompanying drawings. Throughout the figures used in the following description, layers and members are scaled to a perceivable size.

(Magnetic Multi-Layered Film)

First, a tunnel junction device having a TMR film as an example of a multi-layered film including a magnetic layer, and an MRAM including the tunnel junction device will be described.

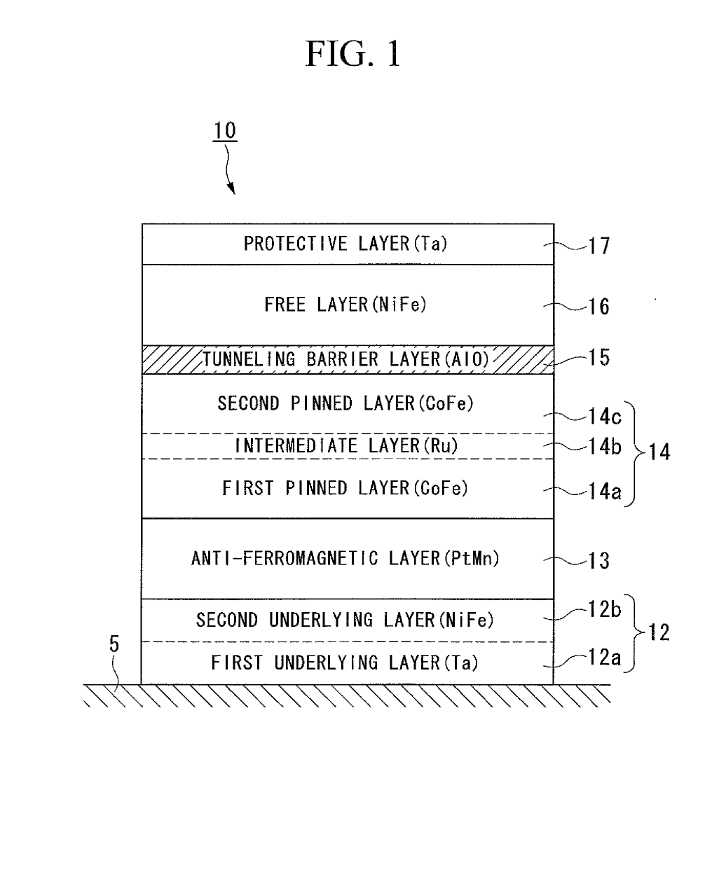

FIG. 1 is a side sectional view showing a tunnel junction device. In the tunnel junction device 10, an underlying layer 12 is formed on a surface of a substrate 5. The underlying layer 12 includes a first underlying layer 12a made of Ta or the like and a second underlying layer 12b made of NiFe or the like. An anti-ferromagnetic layer 13 made of PtMn, IrMn or the like is formed on a surface of the underlying layer 12. The second underlying layer 12b has a function of arranging crystallinity of the anti-ferromagnetic layer 13. A pinned layer (first magnetic layer) 14 is formed on a surface of the anti-ferromagnetic layer 13. The anti-ferromagnetic layer 13 has a function of fixing a magnetization direction of the pinned layer 14. The pinned layer 14 is a laminated ferri-type pinned layer including a first pinned layer 14a made of CoFe or the like, an intermediate pinned layer 14b made of Ru or the like, and a second pinned layer 14c made of CoFe or the like. With this configuration, the magnetization direction of the pinned layer 14 is strongly fixed.

A tunnel barrier layer (non-magnetic layer) 15 made of an electrical insulating material such as AlO (representing aluminum oxide in general, including alumina) or the like is formed on a surface of the pinned layer 14. The tunnel barrier layer 15 is formed by oxidizing a metal aluminum layer having the thickness of about 10 Angstroms. A free layer (second magnetic layer) 16 made of NiFe or the like is formed on a surface of the tunnel barrier layer 15. A magnetization direction of the free layer 16 can be inverted by applying a magnetic field around the tunnel junction device 10. A protective layer 17 made of Ta or the like is formed on a surface of the free layer 16. In addition, an actual tunnel junction device has a multi-layered structure having 15 layers including functional layers in addition to the above-mentioned layers.

In the tunnel junction device 10, resistance of the tunnel junction device 10 is varied depending on whether the magnetization direction of the pinned layer 14 is parallel or anti-parallel to the magnetization direction of the free layer 16; and accordingly, the intensity of current flowing through the tunnel barrier layer 15 is varied when a voltage is applied to the tunnel junction device 10 in its thickness direction (TMR effect). Thus, a binary value ‘1’ or ‘0’ can be read by detecting the intensity of current. In addition, when the magnetization direction of the free layer is inverted by applying the magnetic field around the tunnel junction device 10, the binary value ‘1’ or ‘0’ can be rewritten.

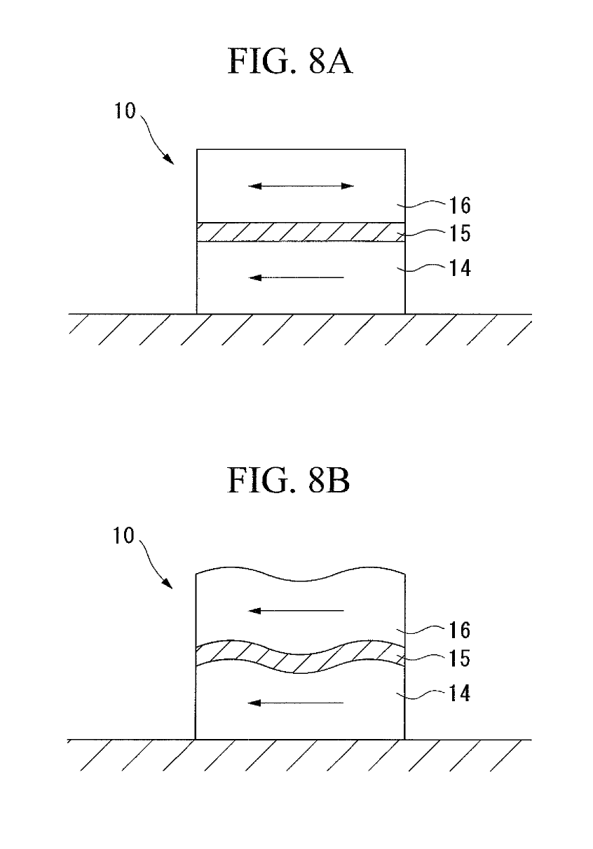

In such a tunnel junction device 10, if there is a deviation in the film thickness in each layers of the pinned layer 14 and the below layers, the tunnel barrier layer 15 laminated on the pinned layer 14 becomes uneven (see FIG. 8B). This may cause a magnetic Neel coupling between the pinned layer 14 and the free layer 16 with the tunnel barrier layer 15 interposed therebetween. As a result, preservation power of the magnetization direction in the free layer 16 increases; and accordingly, a high magnetic field is required to invert the magnetization direction and the magnitude of the required magnetic field becomes irregular. Accordingly, there is a need to flatten the tunnel barrier layer.

(Apparatus for Manufacturing Magnetic Multi-Layered Film)

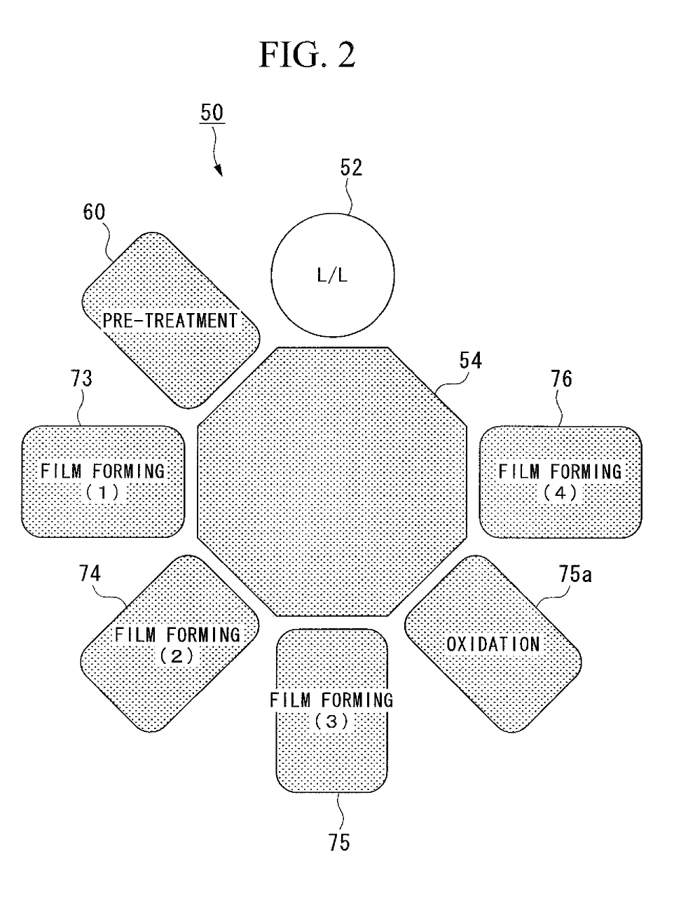

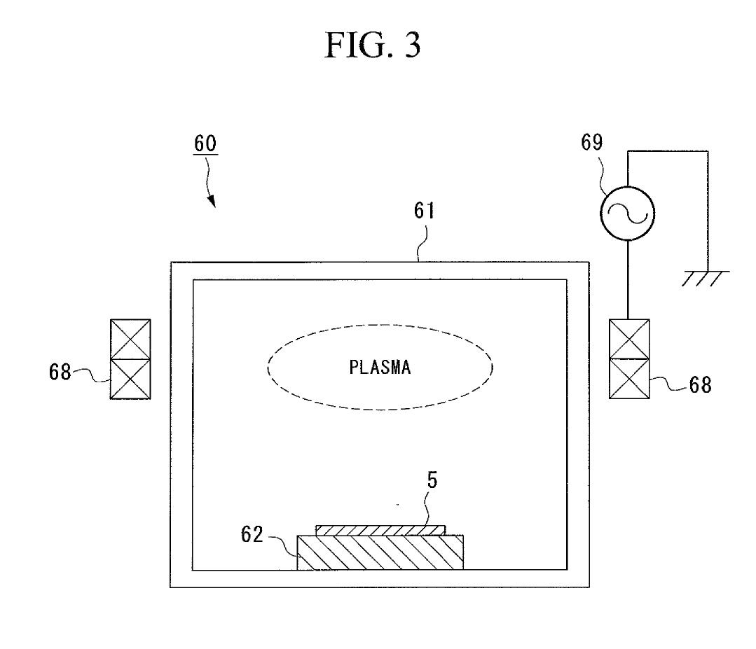

An apparatus for manufacturing a magnetic multi-layered film according to an embodiment of the present invention will be described with reference to FIGS. 2 and 3.

FIG. 2 is a schematic view showing a configuration of an apparatus for manufacturing a magnetic multi-layered film according to an embodiment of the present invention. The apparatus for manufacturing the magnetic multi-layered film according to the embodiment of the present invention includes, as main components, a first sputtering apparatus 73 for performing a film forming process (1) for an anti-ferromagnetic layer, a second sputtering apparatus 74 for performing a film forming process (2) for a pinned layer, a plasma treatment apparatus 60 for performing plasma treatment as pre-treatment before a tunnel barrier layer is formed, a third sputtering apparatus 75 for performing a film forming process (3) for metal aluminum, a heat treatment apparatus 75a for performing an oxidizing process of metal aluminum, and a fourth sputtering apparatus 76 for performing a film forming process (4) for a free layer. In addition, these apparatuses are radially arranged around a substrate transfer chamber 54. With this configuration, the magnetic multi-layered film can be formed on a substrate which is transferred into the apparatus for manufacturing the magnetic multi-layered film according to the embodiment of the present invention, without the substrate being exposed to the air.

FIG. 3 is a schematic view showing a configuration of a plasma treatment apparatus. In this embodiment, a plasma treatment apparatus 60 of an inductive coupling plasma (ICP)-type is employed since this ICP type can further separate the plasma from the substrate, thereby further reducing damage to the substrate, as compared to a capacitive coupling-type having a magnet, since it is difficult for the capacitive coupling-type to control a magnetic field and make the plasma uniform.

In this embodiment, the plasma treatment apparatus 60 includes a chamber 61 having a wall made of quartz or the like. A table 62 on which the substrate 5 is placed is provided on an inner side of the bottom of the chamber 61. The table 62 is made of an electrical insulating material so that the placed substrate remains in an electrical floating state. In addition, the substrate may be grounded through the table 62. On the other hand, an RF antenna 68 for generating plasma inside the chamber 61 is provided outside the side of the chamber 61 and is connected with an RF power source 69. In addition, although not shown, a process gas introduction device for introducing a process gas such as an argon gas and an exhausting device for exhausting a processed gas are provided inside the chamber 61.

(Method of Manufacturing Magnetic Multi-Layered Film)

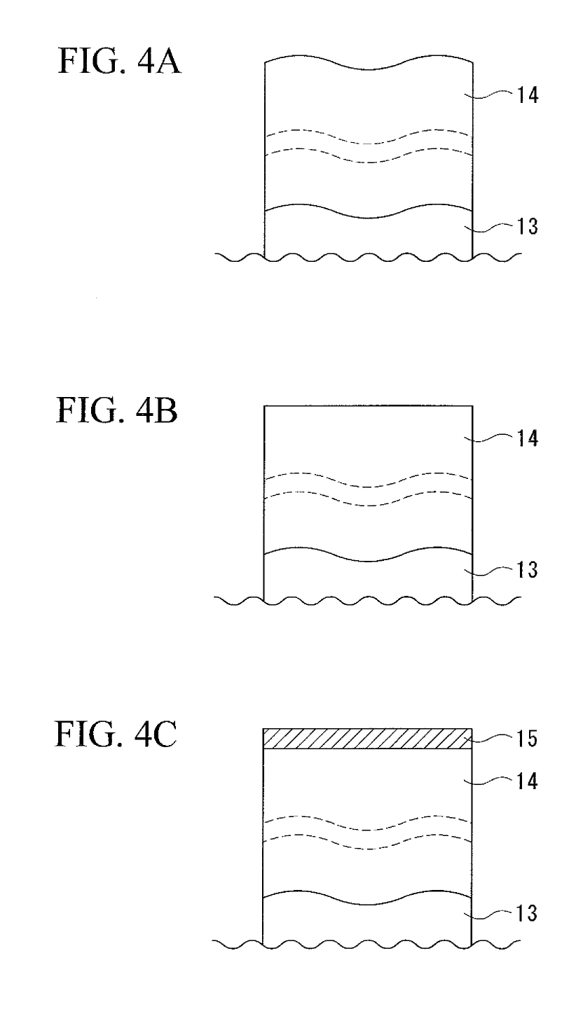

Next, a method of manufacturing a magnetic multi-layered film according to an embodiment of the present invention will be described with reference to FIGS. 4A to 7.

FIGS. 4A to 4C are explanatory views illustrating a method of manufacturing the magnetic multi-layered film according to the embodiment of the present invention. The method of manufacturing the magnetic multi-layered film according to the embodiment of the present invention is to treat the surface of the pinned layer 14 using the plasma treatment apparatus of the inductive coupling plasma-type, with the substrate electrically insulated, before the tunnel barrier layer 15 is formed.

First, using the magnetic multi-layered film manufacturing apparatus as shown in FIG. 2, the underlying layer 12 (the first underlying layer 12a and the second underlying layer 12b), the anti-ferromagnetic layer 13 and the pinned layer 14 are sequentially formed on the surface of the substrate 5 (a first underlying layer forming process, a second underlying layer forming process, an anti-ferromagnetic layer forming process, and a first magnetic layer forming process), as shown in FIG. 1.

Here, if there are deviations in the film thickness in the underlying layer 12, the anti-ferromagnetic layer 13, or the pinned layer 14, the surface of the uppermost pinned layer 14 has unevenness as shown in FIG. 4A. When the tunnel barrier layer is formed on the surface of the pinned layer 14, the tunnel barrier layer also has unevenness as shown in FIG. 8B.

Therefore, the surface of the pinned layer is planarized using the plasma treatment (plasma treatment process), as shown in FIG. 4B. This plasma treatment process is performed using the plasma treatment apparatus 60 shown in FIG. 3. Specifically, first, the substrate 5 on which the pinned layer and the below layers are formed is placed on the table 62 within the chamber 61. At this time, the substrate 5 remains electrically insulated by keeping the substrate 5 in an electrical floating state, or the substrate 5 is grounded, so that a bias voltage is not applied to the substrate 5. Next, a process gas such as an argon gas is introduced into the chamber 61 that forms a vacuum. Next, the RF power source 69 supplies high frequency power to the RF antenna 68 to generate plasma within the chamber 61. The pressure of argon plasma is preferably 0.05-1.0 Pa, for example, 0.9 Pa. The process gas activated by the plasma slowly reacts with the surface of the substrate 5, thereby planarizing the surface of the pinned layer.

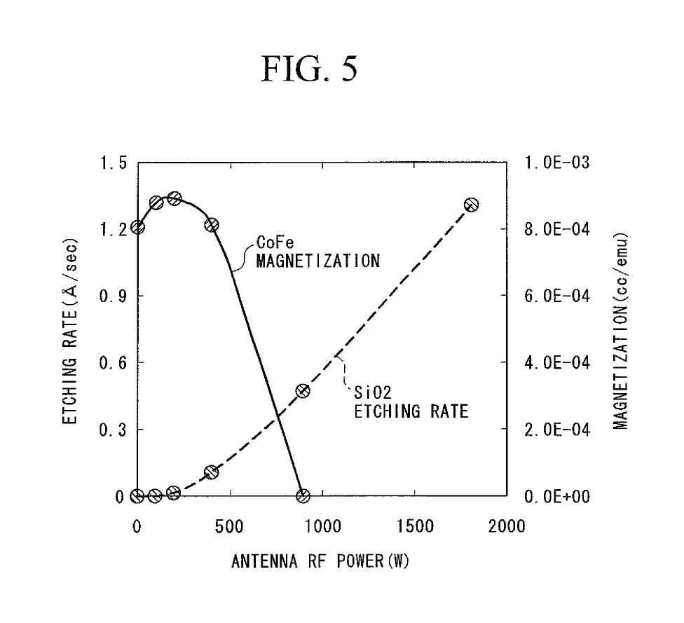

FIG. 5 is a graph showing a relationship between the power supplied to the RF antenna and an etching condition. In FIG. 5, a curve representing an etching rate is for SiO₂, which facilitates measurement of an etching quantity, not for CoFe of which the pinned layer is made. This is because it is believed that an etching rate of CoFe has the same inclination as the etching rate of SiO₂. The etching rate of SiO₂ becomes very small if the power supplied to the RF antenna is equal to or less than 400 W, particularly, nearly 0 if the power is equal to or less than 300 W. Accordingly, in this case, it is believed that only the surface of the pinned layer is planarized without the pinned layer being etched.

In addition, FIG. 5 also shows a curve representing magnetization of CoFe after the plasma treatment. This is because, if the pinned layer is etched to decrease its thickness, the magnetization of the pinned layer also decreases proportionally. The magnetization of CoFe is substantially constant if the power supplied to the RF antenna is equal to or less than 400 W, while suddenly decreasing if the power is more than 400 W. This result supports the belief that only the surface of the pinned layer is planarized without the pinned layer being etched if the power supplied to the RF antenna exceeds 400 W.

As described above, in this embodiment, the above-described plasma treatment process is performed when the power supplied to the RF antenna is equal to or less than 400 W (preferably equal to or less than 300 W). This allows the surface of the pinned layer to be planarized without deteriorating the performance of the pinned layer since the pinned layer is not etched. In addition, a degree of the planarization can be controlled by adjusting the power supplied to the RF antenna depending on a distance between the plasma and the substrate. In addition, power required to maintain the plasma is at least 5W.

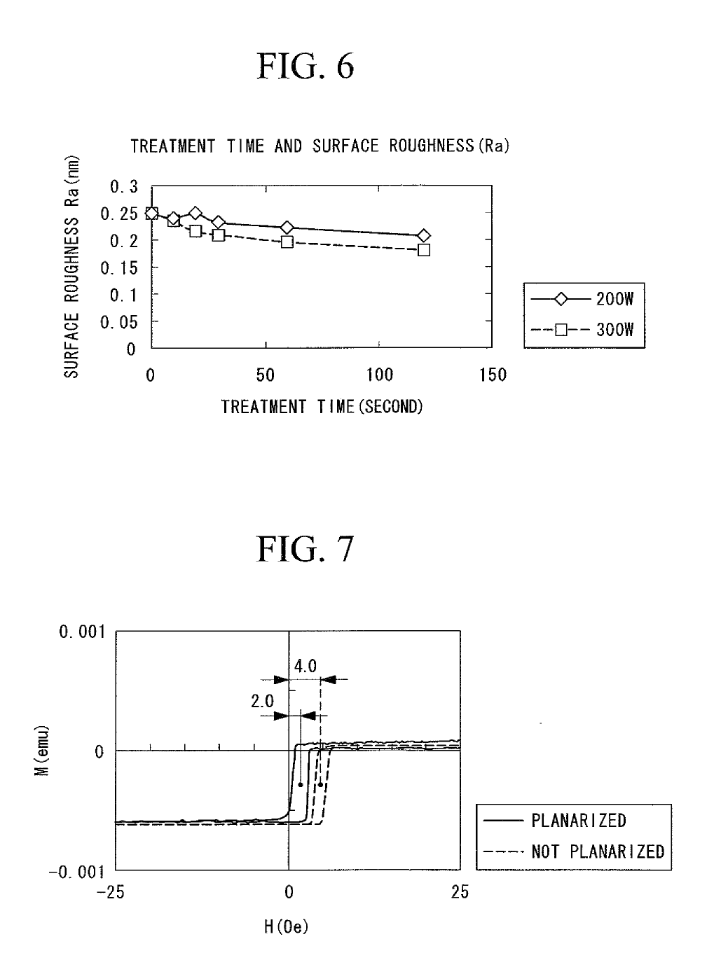

FIG. 6 is a graph showing a relationship between a plasma treatment time and a surface roughness of the pinned layer. This graph shows a result of measurement of a center line average roughness Ra after the plasma treatment for a prescribed time when the power supplied to the RF antenna is 200 W and 300 W.

In this embodiment, the plasma treatment time is in the range of 10 to 30 seconds. It can be seen from FIG. 6 that the surface roughness of the pinned layer, which is about 0.25 nm before the plasma treatment, decreases to about 0.2 nm after the plasma treatment with the power of 300 W for 30 seconds. In this manner, the surface of the pinned layer can be planarized using the method of manufacturing the magnetic multi-layered film according to the embodiment of the present invention. In addition, since the pinned layer is etched as the plasma treatment time becomes long, it is preferable that the plasma treatment time be within 180 seconds.

In addition, as shown in FIG. 4C, the tunnel barrier layer 15 is formed on the surface of the pinned layer 14 (the non-magnetic layer forming process). Specifically, a metal aluminum layer is formed on the surface of the pinned layer 14, and the tunnel barrier layer 15 made of AlO is formed by oxidizing the metal aluminum layer. Since the surface of the pinned layer 14 is planarized as described above, the tunnel barrier layer 15 can be flatly formed. Thereafter, the free layer 16 shown in FIG. 1 is formed on the surface of the tunnel barrier layer 15 (the second magnetic layer forming process), and then the protective layer 17 is formed on the free layer 16 sequentially. Thus, the magnetic multi-layered film 10 shown in FIG. 1 is completed.

FIG. 7 is a graph showing a VSM (vibrating sample magnetometer) analysis result of the magnetic multi-layered film. In FIG. 7, the magnetic multi-layered film having the pinned layer planarized according to this embodiment is indicated by a solid line, and a magnetic multi-layered film having a pinned layer not planarized is indicated by a dotted line.

In the case in which the pinned layer is not planarized, since a tunnel barrier layer has unevenness, a Neel coupling between the pinned layer and a free layer becomes strong. As a result, a high magnetic field is required to invert a magnetization direction of the free layer. For example, a loop shift of the dotted line of FIG. 7 is about 4.0 Oe (Oersted). On the contrary, in the magnetic multi-layered film having the planarized pinned layer, since the tunnel barrier layer is flatly formed, a Neel coupling between the pinned layer and the free layer becomes weak. As a result, a small magnetic field is sufficient to invert a magnetization direction of the free layer. For example, a loop shift of the solid line of FIG. 7 is reduced by half to about 2.0 Oe.

As described above, in the magnetic multi-layered film manufacturing method according to the embodiment of the present invention, the substrate is electrically insulated from the plasma treatment apparatus 60 or is grounded before the tunnel barrier layer as the non-magnetic layer is formed, and then the surface of the pinned layer is subjected to the inductive coupling-type plasma treatment. With this configuration, since the bias voltage is not applied to the substrate, ions of the process gas, which are generated by the plasma, are not introduced into the substrate. Accordingly, the surface of the pinned layer can be planarized without the pinned layer being damaged by being etched, for example. Accordingly, the tunnel barrier layer can be flatly laminated without deteriorating the performance of the magnetic multi-layered film. As a result, since the Neel coupling between the pinned layer and the free layer becomes weak, a high magnetic field is not required to invert the magnetization direction of the free layer and the intensity of the magnetic field required does not become irregular.

In addition, although it has been illustrated in this embodiment that the surface of the pinned layer is planarized, surfaces of layers other than the pinned layer may be planarized before the tunnel barrier layer is formed. However, since the intermediate pinned layer 14b has a function of strongly fixing the magnetization direction of the pinned layer 14, it is not preferable to perform the plasma treatment process before and after forming the intermediate pinned layer 14b. In addition, since the anti-ferromagnetic layer 13 also has a function of fixing the magnetization direction of the pinned layer 14, it is not preferable to perform the plasma treatment process for a surface of the anti-ferromagnetic layer 13. In addition, since the second underlying layer 12b has a function of arranging the crystallinity of the anti-ferromagnetic layer 13, it is not preferable to perform the plasma treatment process for a surface of the second underlying layer 12b. Accordingly, when a surface of a layer other than the pinned layer is to be planarized, it is preferable to planarize a surface of the first underlying layer 12a using the plasma treatment process.

In addition, before the tunnel barrier layer is formed, the tunnel barrier layer 15 can be more flatly laminated if a plurality of layer surfaces is planarized. However, there is a need to adjust an antinomy between the flatness of the tunnel barrier layer 15 and its production efficiency. If a GMR film is formed on a substrate to manufacture a device such as a magnetic head or the like, as disclosed in the above Patent Document 1, the production efficiency is not significant since a large number of devices can be obtained from one substrate. However, when the TMR film is formed on the substrate to manufacture the MRAM or the like, as described in this embodiment, the production efficiency is a matter of great importance since a small number of MRAMs can be obtained from one substrate. Here, since the tunnel barrier layer is laminated on the surface of the pinned layer, it is most effective to planarize the surface of the pinned layer in order to flatten the tunnel barrier layer. Accordingly, by planarizing only the surface of the pinned layer, the tunnel barrier layer can be flattened while minimizing a decrease in the production efficiency accompanied by the plasma treatment.

The technical scope of the present invention is not limited to the above-described embodiments, but is to be construed to include various modifications of the embodiments without departing from the spirit of the present invention. That is, detailed materials, constructions, manufacturing conditions and so on described and shown in the embodiments are only by way of an example, but may be modified in various ways.

### INDUSTRIAL APPLICABILITY

The present invention is adapted to the formation of a film constituting a semiconductor device, such as a GMR spin valve constituting a magnetic head, a TMR device constituting a MRAM and so on.

What is claimed is:

1. A method of manufacturing a magnetic multi-layered film, comprising:
a first magnetic layer forming step of forming a first magnetic layer on a substrate;
a non-magnetic layer forming step of forming a non-magnetic layer on the first magnetic layer; and
a second magnetic layer forming step of forming a second magnetic layer on the non-magnetic layer,
wherein the method further comprises, before the non-magnetic layer forming step, a plasma treatment step of introducing the substrate into a plasma treatment apparatus and treating the substrate with inductive coupling-type plasma, with the substrate being electrically insulated from the plasma treatment apparatus.

2. A method of manufacturing a magnetic multi-layered film, comprising:
a first magnetic layer forming step of forming a first magnetic layer on a substrate;
a non-magnetic layer forming step of forming a non-magnetic layer on the first magnetic layer; and
a second magnetic layer forming step of forming a second magnetic layer on the non-magnetic layer,
wherein the method further comprises, before the non-magnetic layer forming step, a plasma treatment step of introducing the substrate into a plasma treatment apparatus and treating the substrate with inductive coupling-type plasma, with the substrate being grounded.

3. The method of manufacturing a magnetic multi-layered film according to claim 1 wherein power supplied to the plasma treatment apparatus is equal to or more than 5 W and equal to or less than 400 W in the plasma treatment step.

4. The method of manufacturing a magnetic multi-layered film according to claim 1 wherein plasma treatment time is within 180 seconds in the plasma treatment step.

5. The method of manufacturing a magnetic multi-layered film according to claim 1 wherein the plasma treatment is performed on a surface of the first magnetic layer contacting the non-magnetic layer in the plasma treatment step.

6. The method of manufacturing a magnetic multi-layered film according to claim 1 wherein the method further comprises before the first magnetic layer forming step:
a first underlying layer forming step of forming a first underlying layer on the substrate;
a second underlying layer forming step of forming a second underlying layer on the first underlying layer; and
an anti-ferromagnetic layer forming step of forming an anti-ferromagnetic layer on the second underlying layer, and wherein
the plasma treatment is performed before the second underlying layer forming step for a surface of the first underlying layer in the plasma treatment step.

7. The method of manufacturing a magnetic multi-layered film according to claim 1 wherein the magnetic multi-layered film is a tunneling magneto-resistance film and the non-magnetic layer is a tunnel barrier layer.
